(19) United States
(12) Patent Application Publication
(10) Pub. No.: US 2026/0013071 A1
(43) Pub. Date: Jan. 8, 2026

(54) ELECTRONIC DEVICE WITH FUNCTION OF INTERNAL TEMPERATURE ADJUSTING

(71) Applicant: LANNER ELECTRONICS INC., New Taipei City (TW)

(72) Inventor: YAO-SHENG HUANG, New Taipei City (TW)

(73) Assignee: LANNER ELECTRONICS INC., New Taipei City (TW)

(21) Appl. No.: 18/945,878

(22) Filed: Nov. 13, 2024

(30) Foreign Application Priority Data
Jul. 8, 2024 (TW) 113125478

(51) Int. Cl. H05K 7/20; H05K 5/02

(52) U.S. Cl. CPC H05K 7/20172; H05K 5/0213

(57) ABSTRACT

An electronic device with function of internal temperature adjusting is disclosed. The electronic device comprises a housing case, at least one intake fan and a heater, in which the housing case has a mounting hole, at least one first vent hole and at least one second vent hole, the intake fan is embedded in the mounting hole, and the heater is disposed in the housing case for facing to the intake fan. By such arrangements, external cold air would be fed into an internal space of the housing case while the heater and the fan work normally, such that the cold air is then heated by the heater so as to become a warm air. As a result, an internal temperature of the housing case is evenly increased by the warm air, thereby making the electronic device be able to be booted normally.

### CROSS-REFERENCE TO RELATED APPLICATIONS

This application claims the priority of Taiwan Patent Application No. 113125478, filed on Jul. 8, 2024, the content of which is incorporated by reference in its entirety.

### BACKGROUND OF THE INVENTION

### 1. Field of the Invention

The present invention relates to the field of electronic device technology, and more particularly, to an electronic device with function of internal temperature adjusting.

### 2. Description of the Prior Art

Owing to the fact that electronic components, chips and/or modules installed in a housing case of an electronic device are limited to normally work in a range of operating temperature, the electronic device is often unable to boot successfully in a particular environment like snowfield or high latitude.

Briefly speaking, unable to boot normally in a low-temperature environment is known as a product design defect of most types of electronic products. In view of that, inventors of the present application have made great efforts to make inventive research and eventually provided an electronic device with function of internal temperature adjusting.

### SUMMARY OF THE INVENTION

The primary objective of the present invention is to disclose an electronic device with function of internal temperature adjusting. The electronic device comprises a housing case, at least one intake fan and a heater, in which the housing case has a mounting hole, at least one first vent hole and at least one second vent hole, the intake fan is embedded in the mounting hole, and the heater is disposed in the housing case for facing to the intake fan. By such arrangements, external cold air would be fed into an internal space of the housing case while the heater and the fan work normally, such that the cold air is then heated by the heater so as to become a warm air. As a result, an internal temperature of the housing case is evenly increased by the warm air, thereby making the electronic device be able to be booted normally.

In order to achieve the aforementioned objective, one embodiment of the electronic device with function of internal temperature adjusting is provided, which comprises:
a housing case, having a first side plate, a second side plate, a third side plate, and a fourth side plate, and accommodating at least one printed circuit board, a plurality of electronic components and at least one electronic chip therein;
at least one mounting hole, being formed on the first side plate of the housing case;
at least one intake fan, being embedded in the at least one mounting hole;
a heater, being disposed in an internal space of the housing case, and being adjacent to or attached onto to the second side plate of the housing case;
at least one first vent hole, being formed on the third side plate of the housing case; and
at least one second vent hole, being formed on the fourth side plate of the housing case;
wherein the second side plate is opposite to the first side plate, the fourth side plate is opposite to the third side plate, the third side plate is connected between the first side plate and the second side plate, and the fourth side plate is connected between the first side plate and the second side plate;
wherein an air drawing side of the intake fan locates at an outside of the housing case, and an air exhaust side of the intake fan is disposed in the internal space of the housing case, such that the heater faces to the air exhaust side of the intake fan.

In one embodiment, the housing case comprises:
a base having a top opening, comprising a bottom plate and four side plates, wherein the four side plates are the first side plate, the second side plate, the third side plate, and the fourth side plate, respectively; and
a cover plater, being connected to the base for shielding the top opening.

In one embodiment, the plurality of electronic components comprises a plurality of electrical connectors, and a plurality of exposing holes are formed on the third side plate, such that the plurality of electrical connectors protrude out of the housing case via the plurality of exposing holes.

In one embodiment, the heater is controlled by an electronic controller, and is selected from a group consisting of ceramic heater, mica heater, metal heater, silicone rubber heater, silicon carbide heater, and thermo-electric converter.

In one embodiment, the heater is selected from a group consisting of a multi-layered-stack thermoelectric generator or a single-layer thermoelectric generator.

In one embodiment, the first side plate consists of a first segment, a first bending segment in connection with the first segment, a recess segment in connection with the first bending segment, a second bending segment in connection with the recess segment, and a second segment in connection with the second bending segment.

In one embodiment, the recess segment is a central segment of the first side plate, and the at least one mounting hole is formed on the recess segment.

In one embodiment, the third side plate, the first segment, the first bending segment, the recess segment, and the intake fan enclose a first air collecting space, and the at least one first vent hole faces the first air collecting space.

In one embodiment, the fourth side plate, the second segment, the second bending segment, the recess segment, and the intake fan enclose a second air collecting space, and the at least one second vent hole faces the second air collecting space.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1A shows a first schematic stereo diagram of an electronic device with function of internal temperature adjusting according to the present invention.

FIG. 1B shows a second schematic stereo diagram of the electronic device with function of internal temperature adjusting according to the present invention.

FIG. 2A shows a first schematic exploded diagram of the electronic device shown as FIG. 1A.

FIG. 2B shows a second schematic exploded diagram of the electronic device shown as FIG. 1B.

FIG. 3 shows a top view of a base, an intake fan and a heater shown as FIG. 2A.

### DETAILED DESCRIPTION OF THE PREFERRED EMBODIMENTS

To more clearly describe an electronic device with function of internal temperature adjusting according to the present invention, embodiments of the present invention will be described in detail with reference to the attached drawings hereinafter.

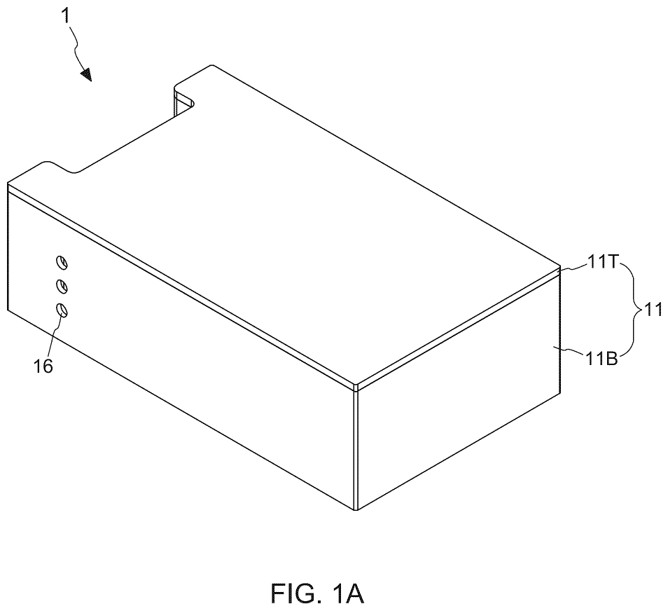

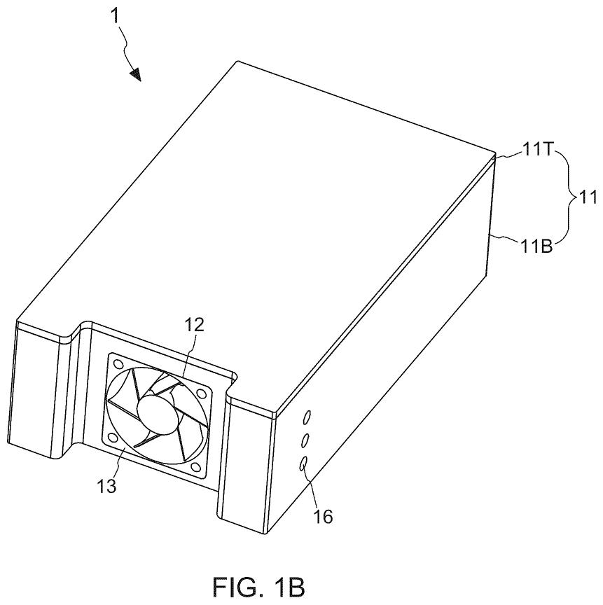

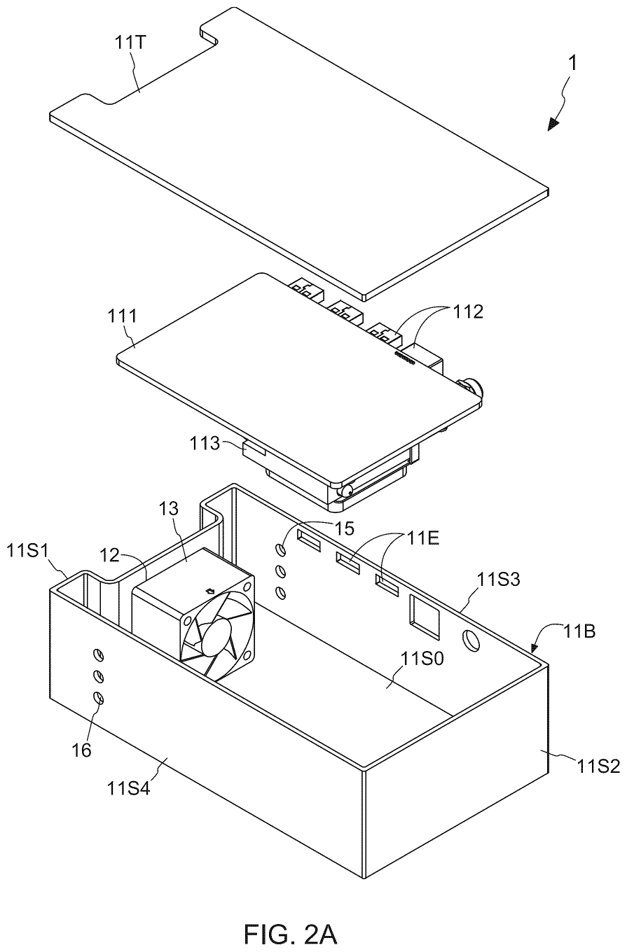

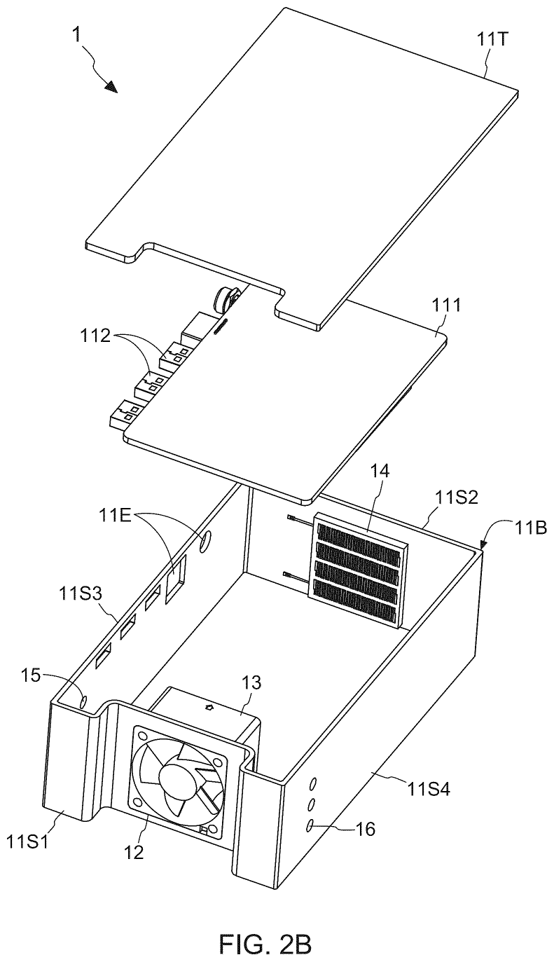

With reference to FIG. 1A and FIG. 1B, there are shown a first schematic stereo diagram and a second schematic stereo diagram of an electronic device with function of internal temperature adjusting according to the present invention. On the other hand, FIG. 2A shows a first schematic exploded diagram of the electronic device shown as FIG. 1A, and FIG. 2B shows a second schematic exploded diagram of the electronic device shown as FIG. 1B. In FIG. 1A, FIG. 1B, FIG. 2A, and FIG. 2B, an electronic device 1 with function of internal temperature adjusting is illustrated, and comprises: a housing case 11, at least one intake fan 13 and at least one heater 14.

As described in more detail below, the housing case 11 consists of a base 11B and a cover plate 11T, of which the housing case 11 comprises a bottom plate 11S0, a first side plate 11S1, a second side plate 11S2, a third side plate 11S3, and a fourth side plate 11S4, and includes a top opening. As FIG. 1A, FIG. 1B, FIG. 2A, and FIG. 2B show, the cover plater 11T is connected to the base 11B for shielding the top opening. Moreover, the housing case 11 accommodates at least one printed circuit board 111, a plurality of electronic components 112 and at least one electronic chip 113 therein.

According to FIG. 1A, FIG. 1B, FIG. 2A, and FIG. 2B, the second side plate 11S2 is opposite to the first side plate 11S1, the fourth side plate 11S4 is opposite to the third side plate 11S3, the third side plate 11S3 is connected between the first side plate 11S1 and the second side plate 11S2, and the fourth side plate 11S4 is connected between the first side plate 11S1 and the second side plate 11S2. It is worth noting that the first side plate 11S1 is formed with at least one mounting hole 12. Moreover, at least one first vent hole 15 is formed on the third side plate 11S3, and at least one second vent hole 16 is formed on the fourth side plate 11S4.

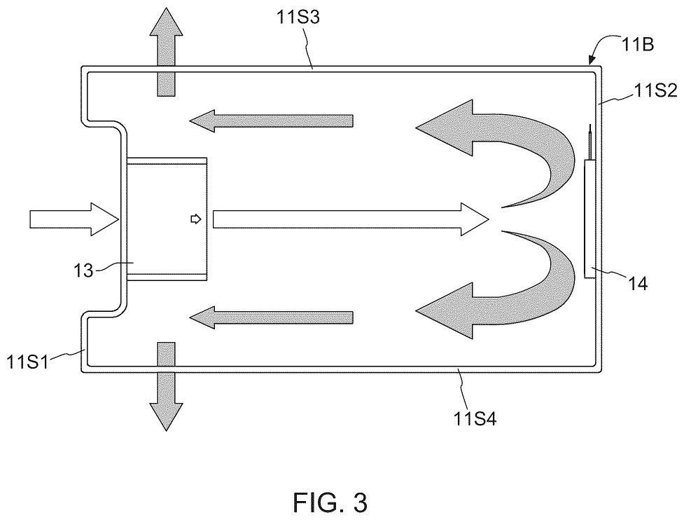

FIG. 3 shows a top view of a base, an intake fan and a heater shown as FIG. 2A. As FIG. 1A, FIG. 1B, FIG. 2A, FIG. 2B, and FIG. 3 show, the intake fan 13 is embedded in the mounting hole 12, and the heater 14 is disposed in an internal space of the housing case 11, and is adjacent to or attached onto to the second side plate 11S2. In practical application, the heater 14 can be, but is not limited to be a ceramic heater, a mica heater, a metal heater, a silicone rubber heater, a silicon carbide heater, or a thermo-electric converter, of which the thermo-electric converter can be a multi-layered-stack thermoelectric generator or a single-layer thermoelectric generator.

As described in more detail below, the intake fan 13 has an air drawing side and an air exhaust side. After being embedded in the mounting hole 12, the air drawing side locates at an outside of the housing case 11, and the air exhaust side is disposed in the internal space of the housing case 11. As such, the heater 14 faces to the air exhaust side of the intake fan 13. In addition, the plurality of electronic components 112 comprises a plurality of electrical connectors, and a plurality of exposing holes 11E are formed on the third side plate 11S3, such that the plurality of electrical connectors protrude out of the housing case 11 via the plurality of exposing holes 11E.

According to FIG. 3, the first side plate 11S1 consists of a first segment, a first bending segment in connection with the first segment, a recess segment in connection with the first bending segment, a second bending segment in connection with the recess segment, and a second segment in connection with the second bending segment, in which the recess segment is a central segment of the first side plate 11S1, and the at least one mounting hole 12 is formed on the recess segment.

FIG. 3 also depict that the third side plate 11S3, the first segment, the first bending segment, the recess segment, and the intake fan 13 enclose a first air collecting space, and the at least one first vent hole 15 faces the first air collecting space. On the other hand, the fourth side plate 11S4, the second segment, the second bending segment, the recess segment, and the intake fan 13 enclose a second air collecting space, and the at least one second vent hole 16 faces the second air collecting space.

By such arrangements, external cold air would be fed into the internal space of the housing case 11 while the heater 14 and the intake fan 13 work normally, such that the cold air is then heated by the heater 14 so as to become a warm air. As FIG. 3 shows, because the intake fan 13 constantly feeds the cold air to the heater 14, a central airflow path is therefore formed between the intake fan 13 and the heater 14. As a result, a first airflow path is formed between the central airflow path and the third side plate 11S3, and a second airflow path is formed between the central airflow path and the fourth side plate 11S4.

Therefore, a part of the warm air produced by the heater 14 is forced to flow along the first airflow path, so as to be collected in the first air collecting space, thereby eventually flowing out of the housing case 11 via the first vent hole 15. Moreover, the other a part of the warm air is forced to flow along the second airflow path, so as to be collected in the second air collecting space, thereby eventually flowing out of the housing case 11 via the second vent hole 16. As a result, an internal temperature of the housing case is evenly increased by the flowing warm air.

In above descriptions, the electronic device 1 with function of internal temperature adjusting according to the present invention have been introduced completely and clearly. It is worth particularly explained that the above description is made on embodiments of the present invention. However, the embodiments are not intended to limit scope of the present invention, and all equivalent implementations or alterations within the spirit of the present invention still fall within the scope of the present invention.

What is claimed is:

1. An electronic device with function of internal temperature adjusting, comprising:
a housing case, having a first side plate, a second side plate, a third side plate, and a fourth side plate, and accommodating at least one printed circuit board, a plurality of electronic components and at least one electronic chip therein;
at least one mounting hole, being formed on the first side plate of the housing case;
at least one intake fan, being embedded in the at least one mounting hole;
a heater, being disposed in an internal space of the housing case, and being adjacent to or attached onto to the second side plate of the housing case;
at least one first vent hole, being formed on the third side plate of the housing case; and
at least one second vent hole, being formed on the fourth side plate of the housing case;
wherein the second side plate is opposite to the first side plate, the fourth side plate is opposite to the third side plate, the third side plate is connected between the first side plate and the second side plate, and the fourth side plate is connected between the first side plate and the second side plate;
wherein an air drawing side of the intake fan locates at an outside of the housing case, and an air exhaust side of the intake fan is disposed in the internal space of the housing case, such that the heater faces to the air exhaust side of the intake fan.

2. The electronic device of claim 1, wherein the housing case comprises:
a base having a top opening, comprising a bottom plate and four side plates, wherein the four side plates are the first side plate, the second side plate, the third side plate, and the fourth side plate, respectively; and
a cover plater, being connected to the base for shielding the top opening.

3. The electronic device of claim 1, wherein the plurality of electronic components comprises a plurality of electrical connectors, and a plurality of exposing holes are formed on the third side plate, such that the plurality of electrical connectors protrude out of the housing case via the plurality of exposing holes.

4. The electronic device of claim 1, wherein the heater is controlled by an electronic controller, and is selected from a group consisting of ceramic heater, mica heater, metal heater, silicone rubber heater, silicon carbide heater, and thermo-electric converter.

5. The electronic device of claim 1, wherein the heater is selected from a group consisting of a multi-layered-stack thermoelectric generator or a single-layer thermoelectric generator.

6. The electronic device of claim 1, wherein the first side plate consists of a first segment, a first bending segment in connection with the first segment, a recess segment in connection with the first bending segment, a second bending segment in connection with the recess segment, and a second segment in connection with the second bending segment.

7. The electronic device of claim 1, wherein the recess segment is a central segment of the first side plate, and the at least one mounting hole is formed on the recess segment.

8. The electronic device of claim 6, wherein the third side plate, the first segment, the first bending segment, the recess segment, and the intake fan enclose a first air collecting space, and the at least one first vent hole faces the first air collecting space.

9. The electronic device of claim 8, wherein the fourth side plate, the second segment, the second bending segment, the recess segment, and the intake fan enclose a second air collecting space, and the at least one second vent hole faces the second air collecting space.
